(19) United States
(12) Patent Application Publication
(10) Pub. No.: US 2026/0239694 A1
(43) Pub. Date: Aug. 13, 2026

(54) TRANSISTOR DEVICE AND MANUFACTURING METHOD THEREOF

(71) Applicant: ProAsia Semiconductor Corporation, Hsinchu City (TW)

(72) Inventors: Ming-Chi Kuo, Hsinchu City (TW); Chen-Hua Lin, Hsinchu City (TW); Pin-Yen Huang, Hsinchu City (TW)

(21) Appl. No.: 19/234,975

(22) Filed: Jun. 11, 2025

(30) Foreign Application Priority Data
Feb. 10, 2025 (TW) 114104839

(51) Int. Cl. H10D 62/13; H01L 21/04; H10D 30/01; H10D 30/66; H10D 62/00; H10D 62/832; H10D 64/23

(52) U.S. Cl. CPC H10D 62/153; H10D 30/0295; H10D 30/66; H10D 62/01; H10D 62/8325; H10D 64/2527; H10P 30/22

(57) ABSTRACT

A transistor device and a manufacturing method thereof are provided. The transistor device includes: a substrate, a first conductive type epitaxial layer, a second conductive type body region, a second conductive type heavily doped recess, and two self-aligned first conductive type heavily doped regions. The first conductive type epitaxial layer is disposed on the substrate, the second conductive type body region is disposed on the first conductive type epitaxial layer, and the second conductive type heavily doped recess is disposed on the second conductive type body region. The two self-aligned first conductive type heavily doped regions are self-aligned and disposed on the upper edges of both sides of the second conductive type heavily doped recess.

### CROSS-REFERENCES TO RELATED APPLICATIONS

This application claims the benefit of priority to Taiwanese Patent Application No. 114104839 filed on Feb. 10, 2025, which is hereby incorporated by reference in its entirety.

### BACKGROUND OF THE INVENTION

### Field of the Invention

This invention relates to a transistor device and a manufacturing method thereof, and in particular to a transistor device capable of enhancing breakdown voltage and reducing critical dimension, and a manufacturing method thereof.

### Descriptions of the Related Art

A Power Metal Oxide Semiconductor Field-Effect Transistor, commonly referred to as a Power MOSFET, is a type of field-effect transistor widely used in analog and digital circuits. It has become the mainstream power device, dominating the market and frequently applied in various electronic power applications. In particular, power transistor devices made using silicon carbide (SiC) substrates have gradually replaced traditional silicon-based power devices, being widely utilized in high-voltage, high-temperature, and low on-resistance high-speed power devices.

For example, traditional silicon-based MOSFETs have reached their physical limits in high-voltage applications, particularly when facing ultra-high voltage and high-frequency switching, where the on-resistance and thermal management properties of silicon materials become inadequate. Additionally, in the manufacturing process of traditional silicon-based MOSFETs, multiple masks and alignment techniques are required. Directly applying these techniques to silicon carbide MOSFETs results in issues such as insufficient mask overlay precision and device breakdown due to parasitic NPN effects, which pose significant obstacles in the design of power transistor devices. Therefore, optimizing the power transistor structure to increase the breakdown voltage while reducing the critical dimension, thereby enhancing device turn-off performance, is an urgent issue to be addressed in the industry.

### SUMMARY OF THE INVENTION

The main objective of this invention is to provide an innovative transistor device and a manufacturing method thereof, featuring self-aligned N-type heavily doped source regions and a P-type heavily doped recess, which mitigate parasitic NPN effects, enhance characteristics for safe operating areas (SOA), and achieve improved device performance by increasing breakdown voltage and reducing critical dimension.

To achieve the above objective, this invention provides a transistor device comprising: a substrate, a first conductive type epitaxial layer, a second conductive type body region, a second conductive type heavily doped recess, and two self-aligned first conductive type heavily doped regions. The first conductive type epitaxial layer is disposed on the substrate, the second conductive type body region is disposed on the first conductive type epitaxial layer, and the second conductive type heavily doped recess is disposed on the second conductive type body region. The two self-aligned first conductive type heavily doped regions are self-aligned and disposed on the upper edges of both sides of the second conductive type heavily doped recess.

In one embodiment of the transistor device of this invention, each self-aligned first conductive type heavily doped region has an ion implantation dose ranging from 1E12 to 1E15 cm⁻².

In one embodiment of the transistor device of this invention, each self-aligned first conductive type heavily doped region has a critical dimension width of 3 to 5 micrometers (μm).

In one embodiment of the transistor device of this invention, the second conductive type heavily doped recess has an ion implantation dose ranging from 1E12 to 1E15 cm⁻².

In one embodiment of the transistor device of this invention, the second conductive type heavily doped recess has a critical dimension width of 1 to 3 micrometers (μm).

In one embodiment of the transistor device of this invention, the substrate is a silicon carbide substrate.

To achieve the above objective, this invention provides a manufacturing method of a transistor device, comprising the following steps: providing a first conductive type epitaxial layer disposed on a substrate; using a first mask to implant second conductive type ions into the first conductive type epitaxial layer to form a second conductive type body region; using a second mask to implant first conductive type ions into the second conductive type body region to form a first conductive type heavily doped region in the second conductive type body region; forming a self-aligned sidewall on the sidewalls of the second mask; using the self-aligned sidewall to etch and remove a portion of the first conductive type heavily doped region and a portion of the second conductive type body region to form a recess structure disposed on the second conductive type body region, while simultaneously forming two self-aligned first conductive type heavily doped regions self-aligned on the upper edges of both sides of the recess structure; and implanting second conductive type ions into the recess structure to form a second conductive type heavily doped recess.

In one embodiment of the manufacturing method of the transistor device of this invention, the step of forming a self-aligned sidewall on the sidewalls of the second mask comprises the following steps: forming an oxide layer covering the second mask and the first conductive type heavily doped region; and etching and removing a portion of the oxide layer to expose the top surface of the second mask and a portion of the first conductive type heavily doped region, while retaining a portion of the oxide layer on the sidewalls of the second mask as the self-aligned sidewall.

In one embodiment of the manufacturing method of the transistor device of this invention, the step of implanting first conductive type ions comprises implanting nitrogen (N) or phosphorus (P) with an ion implantation dose ranging from 1E12 to 1E15 cm⁻².

In one embodiment of the manufacturing method of the transistor device of this invention, the step of implanting second conductive type ions into the recess structure comprises implanting aluminum (Al) with an ion implantation dose ranging from 1E12 to 1E15 cm⁻² to form the second conductive type heavily doped recess.

In one embodiment of the manufacturing method of the transistor device of this invention, the step of forming two self-aligned first conductive type heavily doped regions comprises forming each self-aligned first conductive type heavily doped region with a critical dimension width of 3 to 5 micrometers (μm).

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 8 are schematic diagrams illustrating the manufacturing of a power transistor device in one embodiment of this invention;

FIG. 9 is a cross-sectional schematic diagram of a power transistor device in one embodiment of this invention; and

FIG. 10 is a schematic flowchart of the manufacturing process of a power transistor device in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

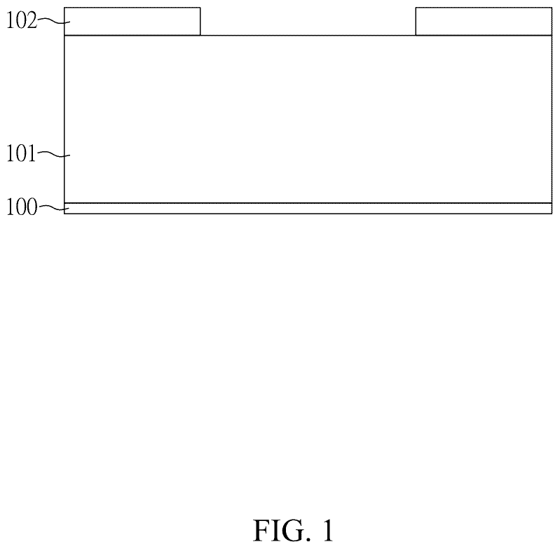

Please refer to FIG. 1 to FIG. 9 together, which illustrate cross-sectional schematic diagrams of manufacturing a power transistor device in one embodiment of this invention. Specifically, this power transistor device is a Vertical Diffused Metal Oxide Semiconductor Field-Effect Transistor (VDMOSFET), as detailed below. The power transistor device comprises a substrate 100. In this embodiment, the substrate 100 is a first conductive type silicon carbide substrate, for example, an N-type heavily doped silicon carbide substrate, to provide a low-resistance channel. A first conductive type epitaxial layer 101 is formed on the substrate 100. This first conductive type epitaxial layer 101 may be, but is not limited to, an N-type lightly doped silicon carbide epitaxial layer, serving as an N-type drift layer with a thickness ranging from several micrometers (μm) to tens of micrometers (μm) and a lower doping concentration of 1E14 to 1E16 cm⁻³, used to withstand high voltages in the power transistor device. In a specific embodiment, the thickness and doping concentration of the first conductive type epitaxial layer 101 are designed based on the voltage withstand requirements of the power transistor device. Subsequently, a photoresist is deposited on the first conductive type epitaxial layer 101, and after a photolithography etching process, a patterned first mask 102 is formed on the first conductive type epitaxial layer 101, as shown in FIG. 1.

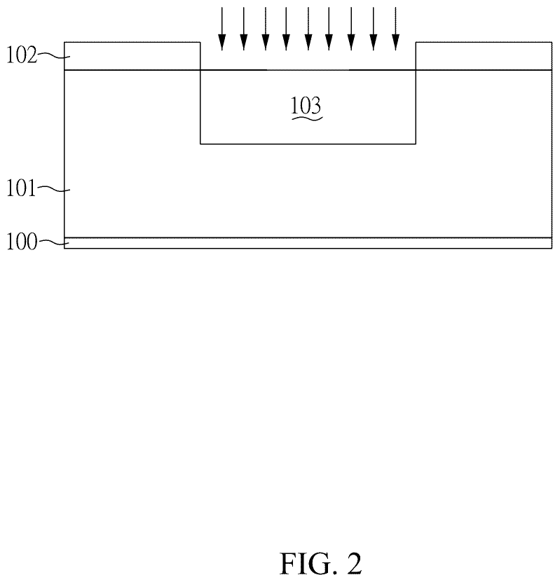

Please refer to FIG. 2, which illustrates performing a blanket second conductive type ion implantation on the first conductive type epitaxial layer 101 using the patterned first mask 102 as an ion implantation mask, thereby defining and forming a second conductive type body region 103 in the first conductive type epitaxial layer 101. In a specific embodiment, the second conductive type body region 103 is a P-type lightly doped body region, with typical P-type dopants being aluminum (Al) or boron (B). Preferably, since aluminum (Al) forms a shallower acceptor level and exhibits good thermal stability, this invention uses aluminum (Al) as the primary P-type dopant, with an ion implantation dose of approximately 1E12 to 1E13 cm⁻².

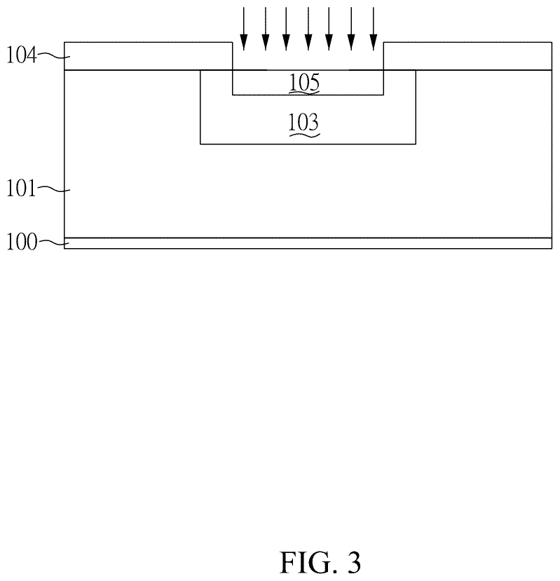

Please refer to FIG. 3, which illustrates depositing and forming a patterned second mask 104 on the first conductive type epitaxial layer 101. Subsequently, using the patterned second mask 104 as an ion implantation mask, a blanket first conductive type ion implantation is performed on the second conductive type body region 103, thereby defining and forming a first conductive type heavily doped region 105 in the second conductive type body region 103. In a specific embodiment, the first conductive type heavily doped region 105 is an N-type heavily doped region, with typical N-type dopants being nitrogen (N) or phosphorus (P). Preferably, this invention uses nitrogen (N) as the primary N-type dopant, with an ion implantation dose of approximately 1E12 to 1E15 cm⁻², to ensure low resistance in the source region of the device and to form a good ohmic contact with the source metal.

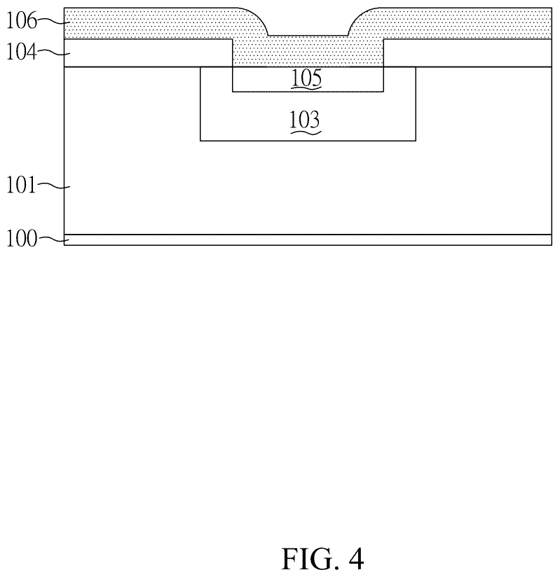

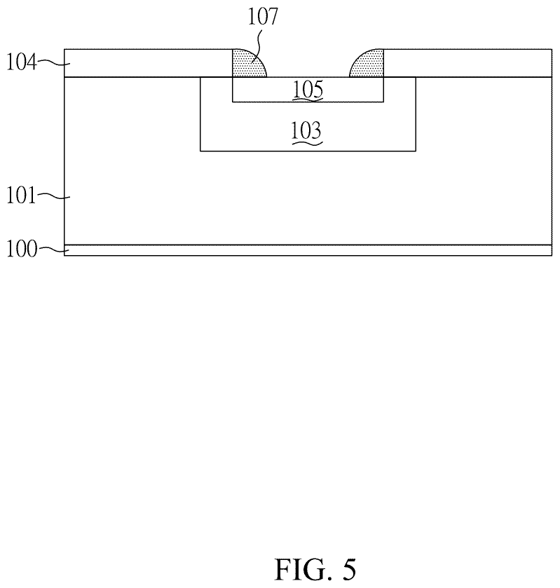

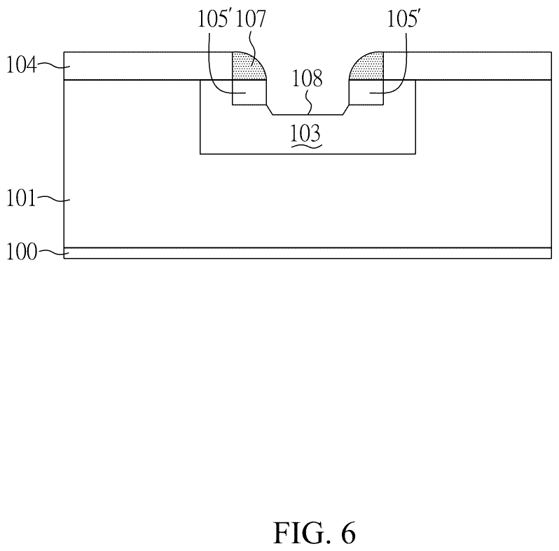

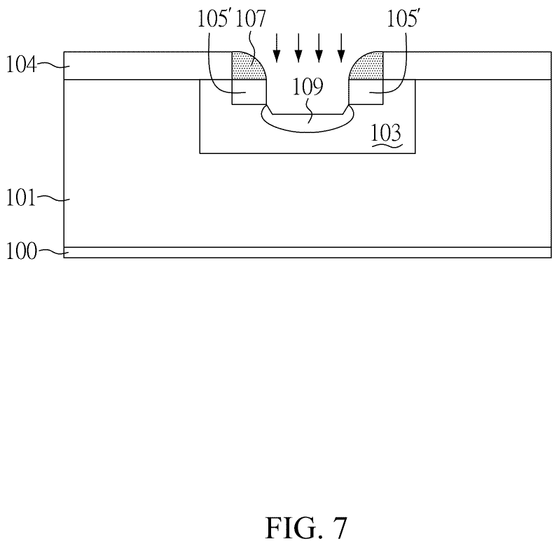

Next, as shown in FIG. 4, an oxide layer 106 is formed to cover the second mask 104 and the first conductive type heavily doped region 105. Then, as shown in FIG. 5, a blanket dry etching of the oxide layer 106 is performed to remove a portion of the oxide layer 106, exposing the top surface of the second mask 104 and a portion of the top surface of the first conductive type heavily doped region 105, while retaining a portion of the oxide layer on the sidewalls of the second mask 104 as a self-aligned sidewall 107 or a spacer. Referring to FIG. 6, using the second mask 104 and the self-aligned sidewall 107 as an etching mask, a portion of the first conductive type heavily doped region 105 and a portion of the second conductive type body region 103 are removed to form a recess structure 108 disposed on the second conductive type body region 103. Additionally, two self-aligned first conductive type heavily doped regions 105′ are simultaneously formed, self-aligned on the upper edges of both sides of the recess structure 108. Specifically, the two self-aligned first conductive type heavily doped regions 105′ may have a critical dimension width of, for example, but not limited to, 3 to 5 micrometers (μm) or smaller. Referring to FIG. 7, similarly, using the second mask 104 and the self-aligned sidewall 107 as a mask, a blanket second conductive type ion implantation process is performed on the recess structure 108 to form a second conductive type heavily doped recess 109. Specifically, aluminum (Al) is used as the P-type dopant, with an ion implantation dose of approximately 1E12 to 1E15 cm⁻², and the second conductive type heavily doped recess 109 has, for example, but not limited to, a critical dimension width of 1 to 3 micrometers (μm).

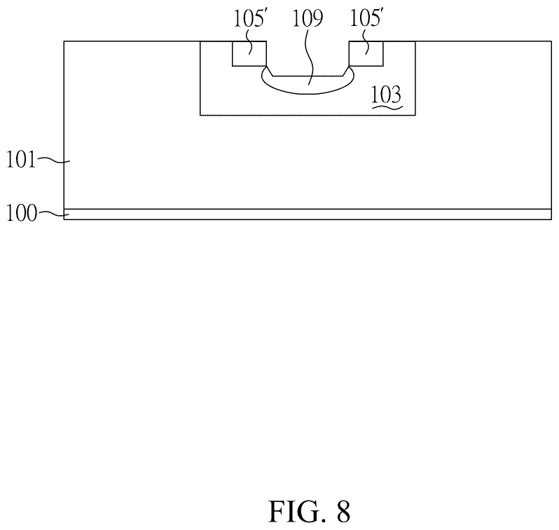

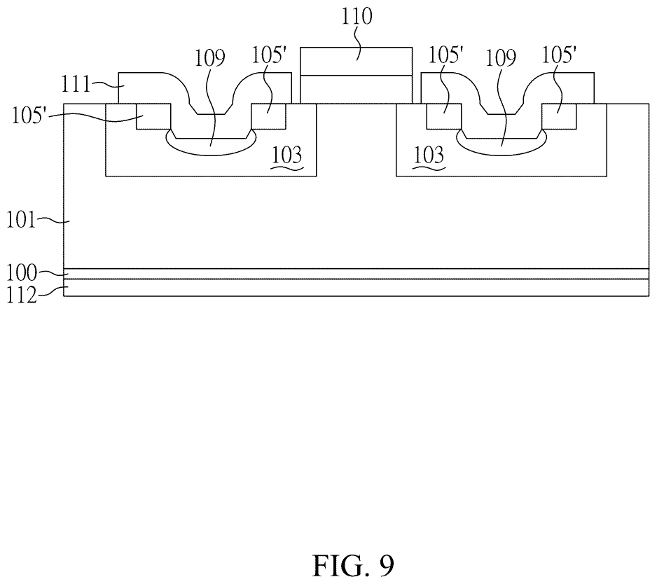

Please refer to FIG. 8 and FIG. 9 together. FIG. 8 illustrates the removal of the second mask 104 and the self-aligned sidewall 107 after forming the two self-aligned first conductive type heavily doped regions 105′ and the second conductive type heavily doped recess 109. FIG. 9 illustrates the subsequent metal contact process, which includes forming a gate metal 110, a source metal 111, and a drain metal 112 for the gate region, source region, and backside drain region, respectively, thereby completing the final structure of the power transistor device of this invention, as shown in FIG. 9.

It should be noted that, as described above, the two self-aligned first conductive type heavily doped regions 105′ and the recess structure 108 in the second conductive type heavily doped recess 109 of the power transistor device structure of this invention are formed simultaneously. Moreover, the two self-aligned first conductive type heavily doped regions 105′ are formed self-aligned on both sides of the recess structure through a self-aligned etching process, rather than using traditional multiple mask exposure and photolithography methods. This approach not only eliminates the need for a mask for the first conductive type heavily doped region, avoiding potential misalignment issues due to insufficient mask overlay precision in traditional processes, but also significantly simplifies the process steps and further reduces the critical dimension (CD) of the device, thereby enhancing the characteristics of safe operating areas (SOA). Additionally, the use of self-aligned and recess structure etching effectively controls the geometry and electric field distribution of the P-type doped body region, thereby increasing the breakdown voltage of the power transistor device of this invention while suppressing parasitic bipolar effects.

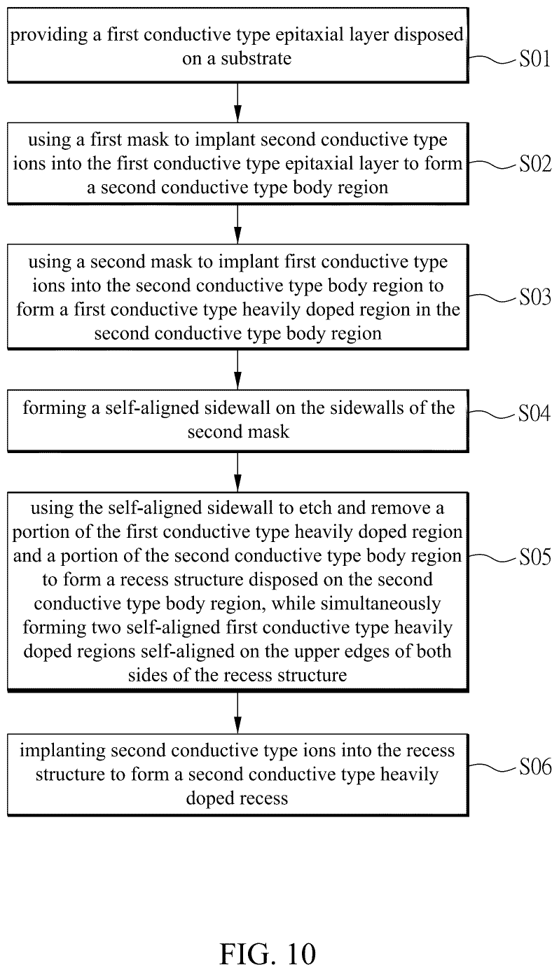

Please refer to FIG. 10, which illustrates a schematic flowchart of the manufacturing process of the power transistor device of this invention. First, in step S01, a first conductive type epitaxial layer is provided on a substrate. In step S02, a first mask is used to implant second conductive type ions into the first conductive type epitaxial layer to form a second conductive type body region. Next, in step S03, a second mask is used to implant first conductive type ions into the second conductive type body region to form a first conductive type heavily doped region in the second conductive type body region. In step S04, a self-aligned sidewall is formed on the sidewalls of the second mask. In step S05, the self-aligned sidewall is used to etch and remove a portion of the first conductive type heavily doped region and a portion of the second conductive type body region to form a recess structure disposed on the second conductive type body region, while simultaneously forming two self-aligned first conductive type heavily doped regions self-aligned on the upper edges of both sides of the recess structure. Finally, in step S06, second conductive type ions are implanted into the recess structure to form a second conductive type heavily doped recess. The details of the components in the aforementioned process steps are described above and will not be repeated here.

In summary, this invention does not use traditional mask overlay methods to control the formation position and width of the N-type heavily doped source region. Instead, it forms a self-aligned sidewall on the second mask originally used for doping the N-type heavily doped source region, thereby simultaneously forming self-aligned N-type heavily doped regions and a P-type heavily doped recess structure. This approach precisely controls the width of the N-type heavily doped source region, achieving a reduced critical dimension, avoiding short-channel effects such as reduced breakdown voltage and parasitic NPN effects caused by photolithography misalignment, and enhancing device performance such as the breakdown voltage of silicon carbide power transistor devices.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A transistor device, comprising:
a substrate;
a first conductive type epitaxial layer disposed on the substrate;
a second conductive type body region disposed on the first conductive type epitaxial layer;
a second conductive type heavily doped recess disposed on the second conductive type body region; and
two self-aligned first conductive type heavily doped regions self-aligned and disposed on the upper edges of both sides of the second conductive type heavily doped recess.

2. The transistor device of claim 1, wherein each of the self-aligned first conductive type heavily doped regions has an ion implantation dose ranging from 1E12 to 1E15 cm⁻².

3. The transistor device of claim 1, wherein each of the self-aligned first conductive type heavily doped regions has a critical dimension width of 3 to 5 micrometers (μm).

4. The transistor device of claim 1, wherein the second conductive type heavily doped recess has an ion implantation dose ranging from 1E12 to 1E15 cm⁻².

5. The transistor device of claim 1, wherein the second conductive type heavily doped recess has a critical dimension width of 1 to 3 micrometers (μm).

6. The transistor device of claim 1, wherein the substrate is a silicon carbide substrate.

7. A manufacturing method of a transistor device, comprising:
providing a first conductive type epitaxial layer disposed on a substrate;
using a first mask to implant second conductive type ions into the first conductive type epitaxial layer to form a second conductive type body region;
using a second mask to implant first conductive type ions into the second conductive type body region to form a first conductive type heavily doped region in the second conductive type body region;
forming a self-aligned sidewall on the sidewalls of the second mask;
using the self-aligned sidewall to etch and remove a portion of the first conductive type heavily doped region and a portion of the second conductive type body region to form a recess structure disposed on the second conductive type body region, while simultaneously forming two self-aligned first conductive type heavily doped regions self-aligned on the upper edges of both sides of the recess structure; and
implanting second conductive type ions into the recess structure to form a second conductive type heavily doped recess.

8. The manufacturing method of the transistor device of claim 7, wherein the step of forming a self-aligned sidewall on the sidewalls of the second mask comprises the following steps:
forming an oxide layer covering the second mask and the first conductive type heavily doped region; and
etching and removing a portion of the oxide layer to expose the top surface of the second mask and a portion of the first conductive type heavily doped region, while retaining a portion of the oxide layer on the sidewalls of the second mask as the self-aligned sidewall.

9. The manufacturing method of the transistor device of claim 7, wherein the step of implanting first conductive type ions is a step of implanting nitrogen (N) or phosphorus (P) with an ion implantation dose ranging from 1E12 to 1E15 cm⁻².

10. The manufacturing method of the transistor device of claim 7, wherein the step of implanting second conductive type ions into the recess structure is a step of implanting aluminum (Al) with an ion implantation dose ranging from 1E12 to 1E15 cm⁻² to form the second conductive type heavily doped recess.

11. The manufacturing method of the transistor device of claim 7, wherein the step of forming two self-aligned first conductive type heavily doped regions is a step of forming each of the self-aligned first conductive type heavily doped regions with a critical dimension width of 3 to 5 micrometers (μm).
